(19) United States
(12) Patent Application Publication
(10) Pub. No.: US 2004/0115859 A1
(43) Pub. Date: Jun. 17, 2004

(54) Organic electroluminescent device and display apparatus

(76) Inventors: Kohji Murayama, Yokohama-shi (JP); Atsushi Tanaka, Sagamihara-shi (JP)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(21) Appl. No.: 10/689,202

(22) Filed: Oct. 20, 2003

(30) Foreign Application Priority Data
Oct. 21, 2002 (JP) 2002-305626

(51) Int. Cl. H01L 21/00; H01L 51/40

(52) U.S. Cl. 438/99; 438/29

(57) ABSTRACT

An organic electroluminescence device comprising a substrate; electrodes including a first electrode formed adjacent to the substrate, and a second electrode disposed to be spaced from the first electrode; a function layer formed between the electrodes and including a luminous layer; and a buffer layer included in the second electrode and disposed to be spaced from the function layer, in which occurrence of dark spots is minimized. Moreover, the present invention provides a method for manufacturing the organic EL device and an organic EL display apparatus.

### BACKGROUND OF INVENTION

The present invention relates to organic electroluminescence (hereinafter, abbreviated as “organic EL”). More specifically, the present invention relates to an organic EL display device improving a problem of occurrence and growth of dark spots, thus making it possible to enhance display quality and a lifetime thereof significantly, and relates to a method for manufacturing the organic EL device, and to an organic EL display using the organic EL device.

An organic EL device has a very fast response speed and is a self-luminous device, and therefore, when the EL device is applied to a display apparatus, it has been expected that a good flat display apparatus with a wide viewing angle can be provided. In this connection, application of the organic EI device to a flat display apparatus succeeding a liquid crystal display apparatus has been studied.

When the above-described organic EL device is applied to the flat display apparatus, an active matrix drive method can be applied thereto similarly to the liquid crystal display apparatus. It has been known that a top emission structure or a bottom emission structure can be adopted as a light emitting structure in the organic EL display apparatus to which the active matrix drive method is applied.

FIGS. 11(a) and 11(b) are views schematically illustrating conventional organic EL devices. FIG. 11(a) illustrates an organic EL device of a top emission type, and FIG. 11(b) illustrates an organic EL device of a bottom emission type. In the conventional organic EL device 100 of the top emission type, which is illustrated in FIG. 11(a), the reflective anode 104 formed of a material such as Ni/Al is deposited on the substrate 102 in many cases, and the function layer 106 composed of an organic EL material is formed on the anode 104. This function layer 106 is composed of a variety of materials in accordance with specific materials and purpose of the organic EL device.

In the conventional example illustrated in FIG. 11(a), on the anode 104, the function layer 106 includes: the carrier injection layer 108 containing copper phthalocyanine and the like; the carrier transport layer 110 such as TPD; and the luminous layer 112 such as Alq3. Moreover, the cathode 114 composed as a transparent conductive film is deposited on the luminous layer 112. In the conventional example illustrated in FIG. 11(a), the cathode 114 is composed of a material such as aluminum (Al). Furthermore, the thin layer 116 composed of a material having small ionization energy, such as Li, K, Ca and Mg, is formed between the cathode 114 and the function layer 106. This thin layer 116 enhances electron injection efficiency.

Moreover, in order to protect the respective constituent components described above from external moisture, the transparent insulating film 118 made of a material such as SiO_{w}, SiOₓN_{y} and SiN_{z} is deposited so as to coat the cathode 114. Thus, a configuration is made, in which the reliability of the organic EL device is enhanced. In the organic EL device 100 of the top emission type, which is illustrated in FIG. 11(a), light generated in the function layer 106 is emitted to the direction indicated by the arrow A.

Moreover, the configuration of the bottom emission type, which is illustrated in FIG. 11(b), has also been known heretofore. On the transparent substrate 122, the conventional organic EL device 120 of the bottom emission type, which is illustrated in FIG. 11(b), includes: the anode 124 composed of a transparent conductive film; the function layer 126 deposited on the anode 124; and the reflective cathode 128 deposited on the function layer 126 and formed of a material, for example, such as Al.

For the function layer 126, materials similar to those of the above-described organic EL device of the top emission type are usable, and a configuration is made, in which light generated in the function layer 126 is emitted to the direction indicated by the arrow B.

It has been known heretofore that a phenomenon seriously affecting the display quality and lifetime of the above-described EL device occurs. Specifically, it has been known that dark spots occur in the EL device. The dark spots are referred to as spotted defects on the organic EL device, where the luminescence is not generated. Such dark spots gradually grow with the elapse of time after the occurrence thereof. Therefore, the existence of the dark spots has become a serious disadvantage in that the luminous area of the organic EL device is reduced which results in the deterioration of the luminance characteristics of the organic EL device, and the display performance is deteriorated with the passage of time.

It has been known that these dark spots are formed by some causes during the manufacture of the device, and that the number of spots is not increased but the area thereof is only expanded with the passage of time. Specifically, it has been conceived that no occurrence of the dark spots during the manufacture of the device will make it possible to enhance the lifetime of the organic EL device significantly and to provide an organic EL device with good display quality.

Various studies have been made to solve the problem of the dark spots. For example, Japanese Patent Laid-Open No. Hei 10(1998)-275682 discloses that a sealing portion is constructed outside the device to prevent the growth of the dark spots due to oxygen and moisture in order to solve the problem of the dark spots. However, in accordance with Japanese Patent Laid-Open No. Hei 10(1998)-275682, the occurrence of the dark spots is not directly prevented. Although the dark spots are made not to be expanded, and thus the lifetime of the device can be prevented from being shortened, the restriction of the occurrence of the dark spots is not an essential object of this disclosed art.

Moreover, such an attempt to prevent the penetration of oxygen and water from the outside is also disclosed in Japanese Patent Laid-Open No. 2000-40594. In Japanese Patent Laid-Open No. 2000-40594, it is studied that an influence from the outside is prevented by forming a damage preventive film on the organic EL device. It is conceived that the damage preventive film disclosed in Japanese Patent Laid-Open No. 2000-40594 prevents damage caused by oxygen, water or plasma, and has some effect on restricting the growth of the dark spots. However, the method disclosed in Japanese Patent Laid-Open No. 2000-40594 never copes with the occurrence of the dark spots to be prevented.

Moreover, in the above-described techniques of preventing the occurrence of the dark spots, the assumption has been made that the dark spots are caused by dust during the manufacture and heterogeneity of films deposited as the anode and cathode. These defects have been coped with by use of methods of reducing the dust and of polishing the deposited films. However, it cannot be said that the occurrence of the dark spots can be inhibited completely according to the conventional coping methods. Furthermore, it has been regarded as necessary to inhibit the occurrence of the dark spots more essentially by solving an essential mechanism in the occurrence of the dark spots.

### SUMMARY OF INVENTION

The present invention is directed to the above-described disadvantages of the background art. The present invention relates to an organic EL device achieving a long lifetime by preventing the deterioration due to the occurrence of the dark spots followed by their growth to achieve the extension of the EL device lifetime by minimizing the occurrence of the dark spots.

Moreover, the present invention relates to a method for manufacturing the organic EL device, and to an organic EL display apparatus including the organic EL device.

The inventors have attained the present invention by studying the occurrence mechanism of the dark spots in detail. Specifically, as a result of the assiduous study, the inventors of the present invention have found that the occurrence of the dark spots is caused by micro delamination on an interface between an organic layer and an inorganic layer. This is as a principal factor besides the dust or the heterogeneity in the deposition on the surface of the deposition layer.

Usually, an inorganic material such as a cathode is deposited on the function layer configuring the organic EL device in order to secure conductivity. What the inventors found out was as follows. In many cases, adhesiveness between an organic film such as a luminous layer and an inorganic film such as the cathode and an anode, which are formed of metal or metal oxide, is not very good. Stress accumulated in each inorganic film causes delamination on the interface between the organic film and the inorganic film, which leads to the occurrence of the dark spots. Once the dark spots occur, oxygen or water permeates along the surface where the layers are delaminated, and thus the dark spots expand for the reasons of corrosion and the like with the elapse of time, thus lowering the long-term reliability of the organic EL device.

The present invention provides the structure of the above-described organic EL device minimizing the occurrence of the dark spots, thus solving the disadvantages inherent in the conventional organic EL device, which are associated with the dark spots.

Specifically, the present invention provides an organic EL device, comprising: a substrate; electrodes including a first electrode formed on the substrate, and a second electrode disposed to be spaced from the first electrode; a function layer formed between the electrodes and including a luminous layer; and a buffer layer included in the second electrode and disposed to be spaced from the function layer.

In the present invention, it is preferable that the buffer layer be formed in a distance of 20 nm or less from an upper end surface of the function layer. In the present invention, the buffer layer contains an oxide. The buffer layer of the present invention can contain aluminum oxide. In the present invention, the organic EL device may further comprise: a layer disposed adjacent to the function layer and containing any of an alkaline metal element and an alkaline earth metal element.

The present invention provides a method for manufacturing an organic EL device, the method comprising the steps of:

forming a first electrode on a substrate;

forming, on the first electrode, a function layer including a luminous layer;

forming a second electrode above the luminous layer; and

forming a buffer layer in a distance of a predetermined value or less from an upper end surface of the function layer.

In the present invention, the buffer layer can contain an oxide, and the step of forming a buffer layer can include any of a step of oxidizing the second electrode and a step of depositing the oxide thereon. In the present invention, the buffer layer can contain aluminum oxide. In the present invention, the manufacturing method can further comprise the step of: depositing a layer containing any of an alkaline metal element and an alkaline earth metal element adjacent to the function layer.

The present invention provides an organic EL display apparatus including a plurality of organic EL devices formed on a substrate,

wherein the organic EL device includes: electrodes including a first electrode adjacent to the substrate, and a second electrode disposed to be spaced from the first electrode; a function layer including a luminous layer formed between the electrodes; and a buffer layer included in the second electrode and disposed to be spaced from the function layer.

In the present invention, the buffer layer can be formed in a distance of 20 nm or less from an upper end surface of the function layer. In the present invention, the buffer layer can contain an oxide. In the present invention, the buffer layer can contain aluminum oxide. In the present invention, the organic EL display apparatus can further comprise: a layer disposed adjacent to the function layer and containing any of an alkaline metal element and an alkaline earth metal element.

### BRIEF DESCRIPTION OF DRAWINGS

For a more complete understanding of the present invention and the advantages thereof, reference is now made to the following description taken in conjunction with the accompanying drawings.

FIG. 1 is a view illustrating a cross-sectional structure of an organic EL device of the present invention, the device having a top emission configuration.

FIG. 2 is a view illustrating a cross-sectional structure of an organic EL device of the present invention, the device having a bottom emission configuration.

FIGS. 3(a) to 3(c) are views illustrating a manufacturing process of the organic EL device of the present invention.

FIGS. 4(a) and 4(b) are views illustrating the manufacturing process of the organic EL device of the present invention.

FIG. 5 is a top view of an organic EL display apparatus of the present invention.

FIG. 6 is a diagram illustrating a drive circuit of the organic EL display apparatus of the present invention.

FIGS. 7(a) and 7(b) are views, each showing luminescence characteristics of one pixel of an organic EL display apparatus (immediately after a manufacture thereof).

FIGS. 8(a) and 8(b) are views, each showing luminescence characteristics of one pixel of the organic EL display apparatus (after the elapse of three weeks).

FIGS. 9(a) and 9(b) are views showing the luminescence characteristics of the organic EL display apparatus of the present invention.

FIGS. 10(a) and 10(b) are views showing the luminescence characteristics of the conventional organic EL display apparatus.

FIGS. 11(a) and 11(b) are views illustrating cross-sectional structures of the conventional organic EL devices.

### DETAILED DESCRIPTION

Although the present invention will be described below by means of embodiments illustrated in the drawings, the present invention is not limited to the embodiments illustrated in the drawings.

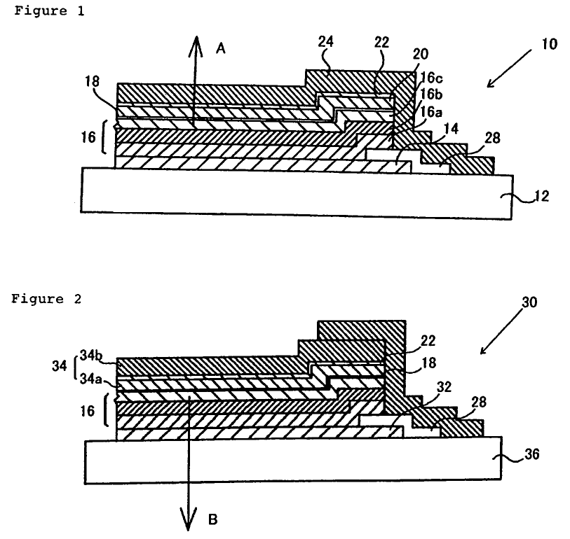

FIG. 1 is a schematic view illustrating the structure of the organic EL device of the present invention. The organic EL device 10 illustrated in FIG. 1 is configured as a structure of a top emission type, in which the reflective anode 14 is deposited on the substrate 12 such as glass, and the function layer 16 for generating luminescence by electroluminescence is deposited on the anode 14. The anode can be formed of a conductive metal material, and for example, Ni, Al, Mo, Cr, Ni/Al and any alloy thereof are usable.

Moreover, as illustrated in FIG. 1, the function layer 16 includes the carrier injection layer 16a, the carrier transport layer 16b and the luminous layer 16c. Note that, in another embodiment of the present invention, the function layer 16 can include another layer having another function, for example, an electron transport layer and the like. Furthermore, in the embodiment illustrated in FIG. 1, the thin layer 18 composed of a material such as LiF is disposed adjacent to the luminous layer 16c.

The carrier generation layer 16a can contain, for example, copper phthalocyanine or the like. However, in the present invention, any carrier generation material, for example, such as porphyrin and the derivative thereof is usable besides the copper phthalocyanine.

Moreover, as the carrier transport layer 16b usable in the present invention, TPD is usable in the specific embodiment of the present invention. However, besides the TPD, any carrier transport material and any derivative thereof, which have been known heretofore, are usable. Such carrier transport materials usable in the present invention will be exemplified below.

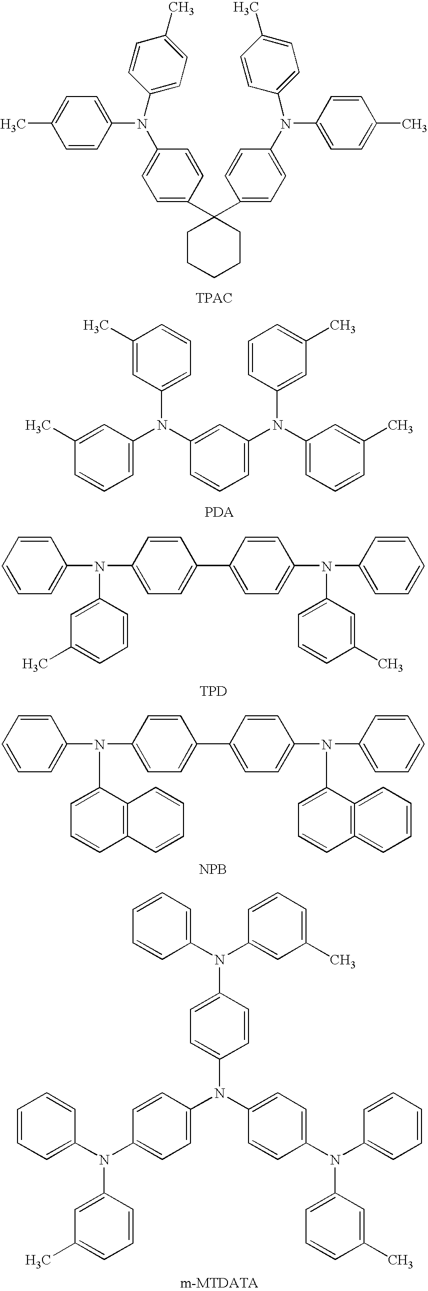

Furthermore, as the luminous layer 16c usable in the present invention, for example, any low-molecular or high-molecular luminescent material known heretofore is usable as well as, for example, a complex such as Alq3. Such luminescent materials usable in the present invention will be described below in an exemplifying manner. As such low-molecular luminescent materials, the following compounds can be listed.

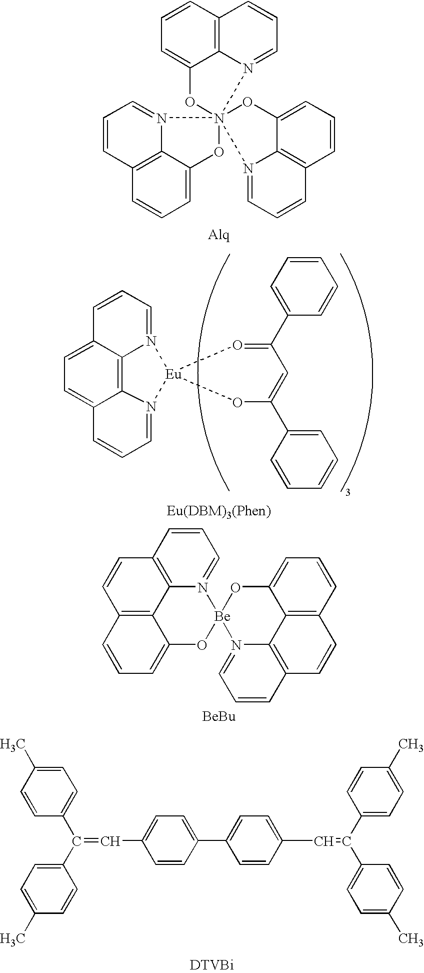

Moreover, as such high-molecular luminescent materials, the following compounds can be listed.

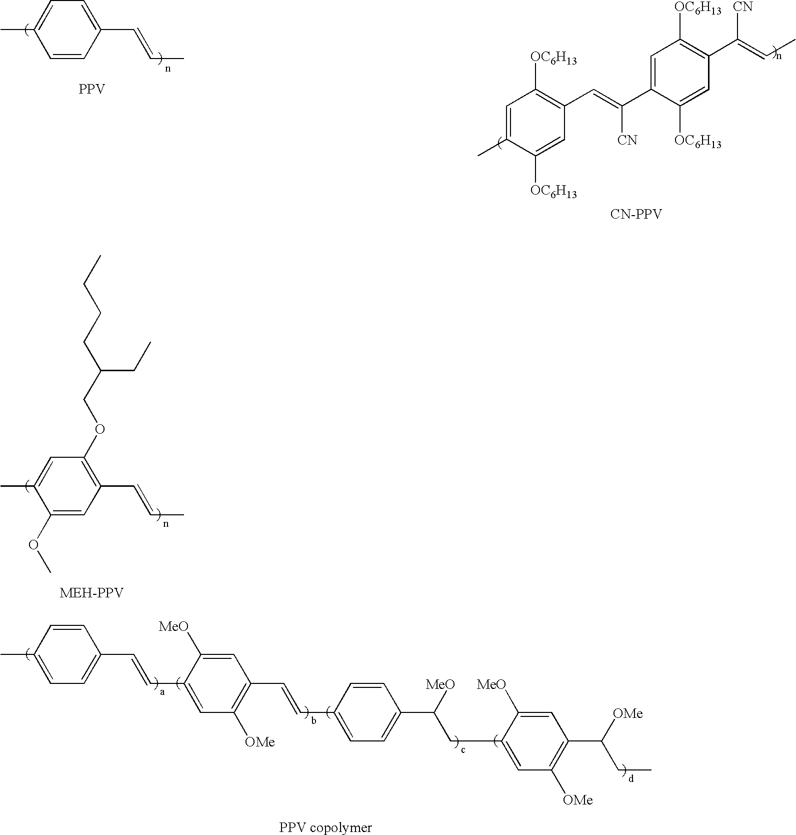

The variety of dopants can be added to the above-described function layer for the purpose of controlling the luminescence characteristics thereof. As the dopants usable in the present invention, any dopant is usable as long as necessary luminescence characteristics can be obtained. For example, the dopant can be selected from a daylight fluorescent material, fluorescent whitener, laser dyestuff, organic scintillator, dyestuff for fluorescence analysis reagent and the like.

More specifically, as the above-described dyestuff, there can be listed Nile Blue, Nile Red, TPB, Coumarin 6, Ketocoumarin, Rubrene, DCM-1 (orange red), Perylene, p-Terphenyl, Polyphenyl 1, Stilbene 1, Stilbene 3, Courmarin 2, Coumarin 47, Coumarin 102, Coumarin 30, Rhodamine 6G, Rhodamine B, Rhodamine 700, Styryl 9, HITCL, IR 140 and the like. However, in the present invention, any dyestuff other than the above-described ones is also usable as long as it can give a suitable luminescence spectrum.

Moreover, in the present invention, an electron transport layer is also usable for the cathode according to need. For the electron layer usable in the present invention, materials exemplified below can be listed.

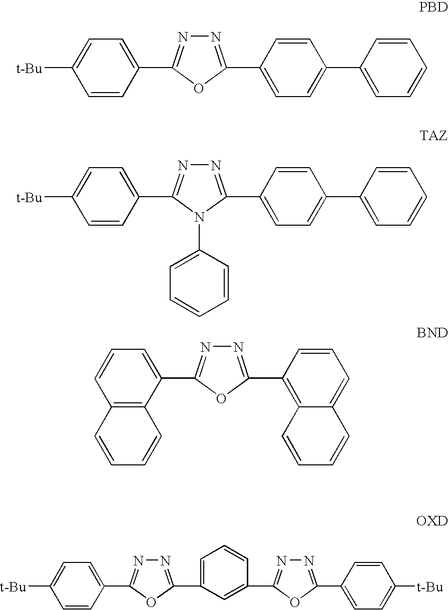

With regard to the above-described materials, in many cases, the low-molecular materials are used in a configuration where the functions thereof are separated into layers and the layers are stacked, and a configuration is adopted, in which the high-molecular material is used as a single layer. However, in the present invention, a variety of dopants can be added to the materials in accordance with light emitting efficiencies thereof, and further, the above-described luminescent materials can be mutually mixed for use.

Such oxadiazole compounds represented by the above formulae or oxadiazole derivatives known heretofore can be listed.

The thin layer 18 for use in the specific embodiment in the present invention can be formed of an optically transparent material having small ionization energy. For example, an alkaline metal element, which includes Li, K and the like, or an alkaline earth metal element, which includes Ca, Mg and the like, is usable. In the specific embodiment of the present invention, the thin layer 18 can be formed of a fluoride such as LiF. Because the above-described thin layer 18 enhances the electron injection efficiency, the thin layer 18 is suitably usable particularly in the case of forming the cathode 20 of Al.

In the present invention, the cathode 20 is formed on the thin layer 18 and configured to supply electrons to the function layer 16. In the specific embodiment of the present invention, the cathode 20 can be formed of Al. As a material for use as the cathode 20 in the bottom type structure, any conductive material is usable although it is preferable for the material to be reflective. For example, Al, Ca, Sr, LiAI, Ni, Ni/Al, Cr, Ag, MgAg and the like are usable. Furthermore, in another embodiment of the present invention, an organic conductive film containing an alkaline metal element or an alkaline earth metal element is usable as the cathode.

In such a case, a conductive film made of metal such as Al, ITO, Ag, Ni and Cr is usable as an auxiliary conductive layer. Furthermore, in the present invention, the buffer layer 22 is formed adjacent to the cathode 20. This buffer layer 22 reduces the stress applied to an organic-inorganic interface from a protective film to be described later.

Thus, delamination on the organic-inorganic interface, and particularly on the Al/function layer interface in the embodiment of the present invention, which is illustrated in FIG. 1, is prevented from being caused. Note that the organic-inorganic interface in the present invention is principally referred to as the Al/function layer interface because the thin layer 18 containing Li is as thin as approximately 0.5 nm.

In the preferred embodiment of the present invention, the above-described buffer layer 22 can be composed as a film having a density lower than the density of the luminous layer 16c or the density of the cathode 20. In the present invention, the density of the layer can be determined by use of, for example, image densities on a cross-sectional structure obtained by a scanning electron microscope.

The above-described buffer layer 22 can contain an oxide in the specific embodiment of the present invention. Particularly in the case of using Al for the cathode 20, it is preferable that Al be used as aluminum oxide. In the present invention, it is preferable that the buffer layer 22 be sufficiently soft and have a density smaller than that of the cathode material so as to be capable of sufficiently buffering the stress applied from the protective film. It is necessary to set the film thickness of the buffer layer 22 for use in the present invention at 50 nm or less in consideration of electron injection properties.

In order to secure sufficient carrier transport properties, it is preferable to set the film thickness at 20 nm or less, and more preferably, in a range from 0.5 nm to 10 nm. In addition, in the present invention, a film thickness obtained by summing those of the cathode 20 and buffer layer 22 can be set at 20 nm or less.

Specifically, in the present invention, a distance to the buffer layer 22 from the upper end surface of the function layer, for example, from the upper end surface of the luminous layer 16c in the embodiment illustrated in FIG. 1, is preferably set at approximately 20 nm or less. In the present invention, for example, when an unillustrated electron transport layer is formed on the luminous layer 16c to compose the function layer 16, the upper end surface of the function layer 16 will coincide with the upper end surface of the electron transport layer.

The protective film 24 for protecting the constituent components such as the function layer 16 and the cathode from external water and oxygen is formed on the buffer layer 22. The protective film 24 can be formed of a material such as SiO_{w}, SiₓO_{y} and SiN_{z} in order to be sufficiently optically transparent and to impart thereto sufficient protection properties.

FIG. 2 illustrates another embodiment of the organic EL device of the present invention. The organic EI device 30 illustrated in FIG. 2 is configured as a bottom emission type. The organic EL device of the bottom emission type, which is illustrated in FIG. 2, is configured to be largely similar to the organic EL device 10 illustrated in FIG. 1 except for the configurations of the anode 32 and the cathode 34. In the embodiment of the organic EL device 30 of the present invention shown in FIG. 2, the anode 32 is deposited on the substrate 36 and formed of a transparent conductive material such as ITO, IZO and SnO₂ in order to enable bottom emission.

Moreover, the cathode 34 of the organic EL device illustrated in FIG. 2 is formed of reflective Al. The cathode 34 is formed as the cathode layers 34a and 34b by a deposition process divided into two steps. On the cathode layer 34a, the buffer layer 22 is formed in a configuration similar to that described with reference to FIG. 1. Moreover, the function layer 16 and the thin layer 18, which are similar to those described in the first embodiment of the present invention, which have been described with reference to FIG. 1, are formed between the cathode 34 and the anode 32, thus configuring the organic EL device. Note that, though the protective layer is not formed in the embodiment illustrated in FIG. 2, the protective layer can be formed similarly to the embodiment illustrated in FIG. 1, thus making it possible to enhance the reliability.

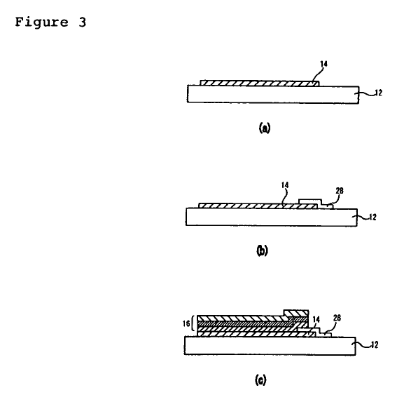

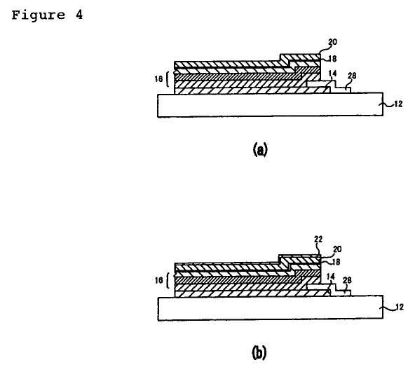

FIGS. 3(a) to 4(b) are views illustrating structures at the respective steps, which are formed by use of a method for manufacturing an organic EL device of the present invention. The embodiment of the manufacturing method illustrated in FIGS. 3(a) to 4(b) is an embodiment of manufacturing the organic EL device 10 having the top emission structure illustrated in FIG. 1. However, the manufacturing method illustrated in FIGS. 3(a) to 4(b) can also be applied to the organic EL device 30 illustrated in FIG. 2 only by changing the materials of the substrate, anode and cathode.

The manufacturing method of the present invention will be described with reference to the drawings from FIG. 3(a). First, as illustrated in FIG. 3(a), a reflective material such as, for example, Ni or Ni/Al is deposited on the substrate such as glass, quartz, fused quartz and silicon (single crystal, polycrystal), and then patterned to form the anode 14. Subsequently, as illustrated in FIG. 3(b), an insulating material such as polymer and SiOₓ is deposited in order to define a conductive component and a pixel, which are adjacent to each other. Then, the insulating material is patterned, and then the insulating structure 28 is formed. Thereafter, as illustrated in FIG. 3(c), the function layer 16 including the carrier generation layer, the carrier transport layer and the luminous layer is deposited by a method such as sputtering and evaporation by use of an appropriate mask.

Furthermore, in the manufacturing method of the present invention, as illustrated in FIG. 4(a), the thin layer 18 containing, for example, LiF, and the cathode 20 are deposited by use of a method such as sputtering or evaporation. Thereafter, as illustrated in FIG. 4(b), the buffer layer 22 is formed on the surface of the cathode 20. In the specific embodiment in the present invention, the buffer layer 22 can be formed in such a manner that oxygen, air and the like are introduced into a manufacturing apparatus, the organic EL device is left as it is for a predetermined period of time at predetermined temperature, and the surface of the cathode 20 is oxidized. Moreover, in another embodiment of the manufacturing method of the present invention, for example, a metal oxide such as aluminum oxide can be deposited by use of a CVD method or the like in order to prepare the buffer layer 22 having an appropriate density.

In this case, the deposition rate can be adjusted so as to obtain the appropriate density. In the present invention, the buffer layer 22 can be formed in a self-aligning manner with the cathode 20 without particularly using a material such as a mask in the case of preparing the buffer layer 22 by use of the surface oxidation of the cathode. Therefore, the manufacturing cost can be reduced, and the manufacturing process can be simplified.

Thereafter, the material such as SiO_{w}, SiOₓN_{y} and SiN_{z} is deposited on the buffer layer 22 by the CVD method to form the protective layer 24. Thus, the organic EL device of the top emission type as illustrated in FIG. 1 is formed. Moreover, prior to forming the protective layer 24, an unillustrated conductive component for performing necessary connections can be formed. Note that the organic EL device of the bottom emission type of the present invention, which is illustrated in FIG. 2, can be formed by changing the materials of the anode and cathode and depositing the cathode material in place of the protective layer 24 in the manufacturing method illustrated in FIGS. 3(a) to 4(b).

Moreover, in the present invention, a configuration is also usable, in which the anode is set as a lower electrode and the cathode is set as an upper electrode seen from the function layer. Alternatively, another configuration is also usable, in which the anode is set as the upper electrode and the cathode is set as the lower electrode seen from the function layer.

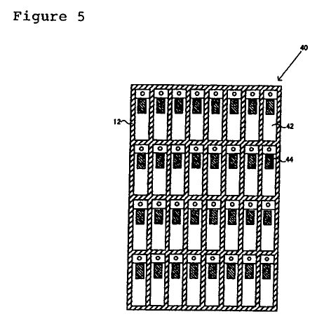

FIG. 5 is a top view illustrating the configuration of the organic EL display apparatus 40 in which the organic EL devices of the present invention are arranged in an active matrix. As illustrated in FIG. 5, the organic EL display apparatus 40 of the present invention is configured as an active matrix arrangement in which the respective pixels 42 are arranged in matrix on the substrate. In the preferred embodiment of the present invention, the thin film transistors (hereinafter, referred to as TFTs) 44 are connected to the respective pixels 42, thus enabling a switching drive for each pixel.

The function layer of which cross-sectional shape is schematically illustrated in FIGS. 1 and 2 is deposited on each pixel 42, thus configuring the organic EL device. The unillustrated conductive components necessary to perform the active matrix drive are formed between the pixels 42, and thus a configuration is made, in which the organic EL display apparatus of the present invention can be driven based on control signals inputted from the outside.

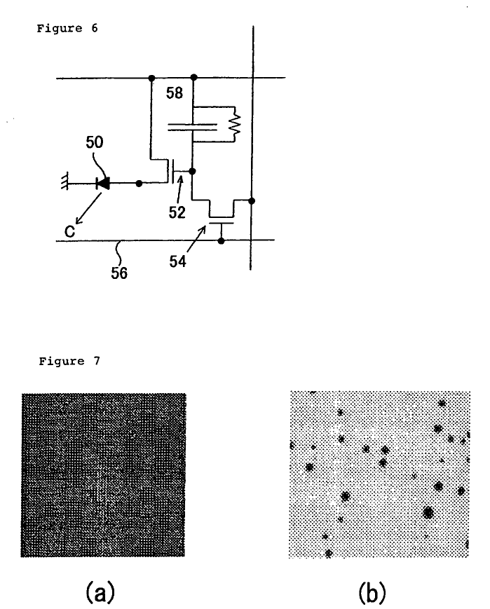

FIG. 6 illustrates one example of the drive circuit of the organic EL device, which is usable in the present invention. In FIG. 6, the organic EL device is illustrated as the diode denoted by the reference numeral 50. In the embodiment of the drive circuit illustrated in FIG. 6, the drive circuit for driving the organic EL device can include the switching TFT 54 for performing the switching drive, the driver TFT 52 driven by the switching TFT 54 and for supplying a current to the organic EL device 50, and the capacitor 58 for stabilizing the current supplied to the organic EL device 50.

The signal line 56 is connected to the switching TFT 54. A drive signal is received through the signal line 56 to drive the switching TFT 54, which then controls the gate potential of the driver TFT 52. Thus, the driver TFT 52 is driven to be switched on and off. The current to the organic EL device 50 is controlled in accordance with the on/off operations of the driver TFT 52, and thus luminescence in the function layer, which is used in the present invention, is obtained as indicated by the arrow C. In the present invention, the above-described circuit for driving the organic EL device is not limited to the one illustrated in FIG. 6, and any circuit known heretofore is usable.

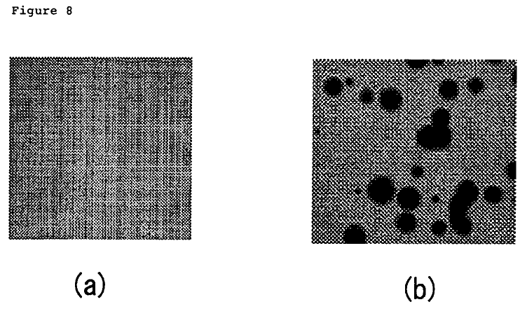

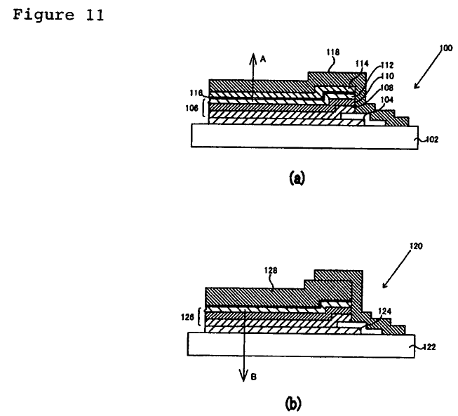

FIGS. 7(a) and 7(b) are views comparing the luminescence characteristics of one pixel of the organic EL display apparatus of the present invention, which uses the organic EL devices of the bottom emission structure, the organic EL devices being illustrated in FIG. 2, with the luminescence characteristics of the conventional organic EL display apparatus illustrated in FIG. 11 immediately after the manufacture thereof. In the organic EL display devices illustrated in FIGS. 7(a) to 9(b), Al was used as the cathodes. The buffer layer was formed in such a manner that the cathode was deposited, dry air was introduced into a deposition apparatus to perform air oxidation for the Al surface, and thus aluminum oxide (Al₂O₃) was formed on the surface of the cathode.

Thereafter, Al was deposited again to form the cathode having a film thickness of approximately 200 nm and including the buffer layer therein, thus configuring the organic EL device. In this case, the density of the buffer layer was estimated by use of the image densities of the cross-sectional structure, which was obtained by scanning electron microscope, and consequently, the density was confirmed to be lower than that of the Al layer. Moreover, the buffer layer was formed to have a film thickness of approximately 2 nm in a distance of approximately 10 nm from the luminous layer. Moreover, the LiF layer was formed in a thickness of approximately 0.5 nm between the cathode and the luminous layer.

FIG. 7(a) shows the luminescence characteristics of one pixel of the organic EL display apparatus of the present invention, and FIG. 7(b) shows the luminescence characteristics of the conventional organic EL device. As shown in FIG. 7(a), no black portions due to the dark spots were observed in the organic EL display apparatus manufactured in accordance with the present invention, and good display quality is exhibited. On the other hand, the conventional organic EL device shown in FIG. 7(b) shows that display defects due to the dark spots occurred therein though the device was manufactured under the same deposition conditions except that the buffer layer used in the present invention was not used.

The manufacturing conditions of the organic EL devices shown in FIGS. 7(a) and 7(b) are the same. Therefore, it is shown that the occurrence of the dark spots can be effectively reduced by buffering the stress remaining on the organic-inorganic interface rather than by reducing the dust and the defective deposition of the electrode.

FIGS. 8(a) and 8(b) are views showing display characteristics obtained by conducting the same display tests for the pixels of the same organic EL devices after the elapse of approximately three weeks. FIG. 8(a) shows the display characteristics of the organic EL display apparatus of the present invention, and FIG. 8(b) shows the display characteristics of the conventional organic EL device.

As shown in FIG. 8(a), when the dark spots do not occur during the manufacture thereof, the display quality is maintained even after the elapse of time. However, when the dark spots occur during the manufacture thereof, the dark spot portions expand with the elapse of time as shown in FIG. 8(b). As a result, the lowering of the display quality such as a lowering of luminance, a lowering of contrast and a display defect will be caused. As indicated in the embodiments shown in FIGS. 7(a) to 8(b), it is understood that it becomes possible to enhance the reliability of the display characteristics of the organic EL display apparatus significantly according to the present invention.

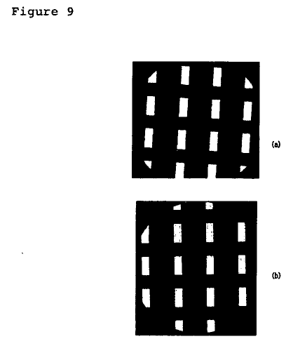

FIGS. 9(a) and 9(b) are views showing a change with time in the luminescence characteristics of the organic EL display apparatus of the present invention in a wider region. FIG. 9(a) is a view showing the luminescence characteristics immediately after the manufacture of the apparatus, and FIG. 9(b) shows the luminescence characteristics observed after the elapse of approximately three weeks after the manufacture thereof. As shown in FIG. 9(a), the organic EL display apparatus of the present invention gives luminescence of which contrast is high along the shape of the pixels. In addition, as shown in FIG. 9(b), also with regard to the change with time in the luminescence characteristics, it is indicated that such a change with time hardly occurs in the organic EL display apparatus of the present invention.

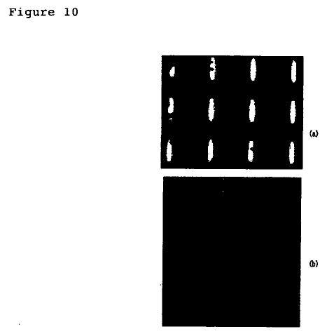

On the other hand, results of a similar study for the conventional organic EL display apparatus are shown in FIGS. 10(a) and 10(b). FIG. 10(a) is a view showing the luminescence characteristics immediately after the manufacture of the apparatus, and FIG. 10(b) is a view showing the luminescence characteristics after the elapse of approximately three weeks after the manufacture. As shown in FIG. 10(a), in the luminescence of the conventional organic EL display apparatus, the lowering of luminance on the peripheries of the pixels is observed in addition to the dark portions caused by the dark spots even immediately after the manufacture.

Although the reason for this is a matter of conjecture at present, it is assumed that the residual stress is prone to be released on the peripheral portions of the pixels, and consequently, the delamination on the organic-inorganic interface is more prone to occur on the peripheral portions of the pixels. Furthermore, in the luminescence characteristics shown in FIG. 10(b), in which the luminescence characteristics are traced with time (approximately for three weeks), the lowering of luminance in each pixel is observed accompanied with the growth of the dark spots, and further, the shape reproducibility of the pixels is lowered. As such, it is shown that the display characteristics of the organic EL display apparatus are deteriorated significantly.

As described above, according to the present invention, the organic EL device minimizing the occurrence of the dark spots essentially and enhancing the reliability of the display characteristics can be provided. Furthermore, according to the present invention, the method for manufacturing easily at low cost the organic EL device capable of reducing the occurrence of the dark spots can be provided. Moreover, according to the present invention, the organic EL display apparatus capable of providing the display at good contrast for a long period of time without causing the deterioration with time in the display characteristics can be provided.

As above, the present invention has been described in detail by means of the embodiments illustrated in the drawings. However, the present invention is not limited to the embodiments illustrated in the drawings. With regard to the configuration of the details, the structure, configuration, manufacturing process order of the organic EL device and the like, any can be appropriately applied as long as a similar configuration can be obtained.

Although the preferred embodiments of the present invention have been described in detail, it should be understood that various changes, substitutions and alternations can be made therein without departing from spirit and scope of the inventions as defined by the appended claims.

What is claimed is:

1. An organic electroluminescent device, comprising:
a substrate;
electrodes including a first electrode formed on the substrate, and a second electrode disposed to be spaced from the first electrode;
a function layer formed between the electrodes and including a luminous layer; and
a buffer layer included in the second electrode and disposed to be spaced from the function layer.

2. The organic electroluminescent device according to claim 1, wherein the buffer layer is formed in a distance of 20 nm or less from an upper end surface of the function layer.

3. The organic electroluminescent device according to claim 1, wherein the buffer layer contains an oxide.

4. The organic electroluminescent device according to claim 1, wherein the buffer layer contains aluminum oxide.

5. The organic electroluminescent device according to claim 1, further comprising:
a layer disposed adjacently to the function layer and containing any of an alkaline metal element and an alkaline earth metal element.

6. A method for manufacturing an organic electroluminescent device, the method comprising the steps of:
forming a first electrode on a substrate;
forming, on the first electrode, a function layer including a luminous layer;
forming a second electrode above the luminous layer; and
forming a buffer layer in a distance of a predetermined value or less from an upper end surface of the function layer.

7. The method for manufacturing an organic electroluminescent device according to claim 6, wherein the buffer layer contains an oxide, and the step of forming a buffer layer includes any of a step of oxidizing the second electrode and a step of depositing the oxide thereon.

8. The method for manufacturing an organic electroluminescent device according to claim 6, wherein the buffer layer contains aluminum oxide.

9. The method for manufacturing an organic electroluminescent device according to claim 6, further comprising the step of: depositing a layer containing any of an alkaline metal element and an alkaline earth metal element adjacent to the function layer.

10. An organic electroluminescent display apparatus including a plurality of organic electroluminescent devices formed on a substrate, wherein the organic electroluminescent device includes:
electrodes including a first electrode adjacent to the substrate and a second electrode disposed to be spaced from the first electrode;
a function layer formed between the electrodes and including a luminous layer; and
a buffer layer included in the second electrode and disposed to be spaced from the function layer.

11. The organic electroluminescent display apparatus according to claim 10, wherein the buffer layer is formed in a distance of 20 nm or less from an upper end surface of the function layer.

12. The organic electroluminescent display apparatus according to claim 10, wherein the buffer layer contains an oxide.

13. The organic electroluminescent display apparatus according to claim 10, wherein the buffer layer contains aluminum oxide.

14. The organic electroluminescent display apparatus according to claim 10, further comprising:
a layer disposed between the luminous layer and the second electrode and containing any of an alkaline metal element and an alkaline earth metal element.
